(19) United States
(12) Patent Application Publication
(10) Pub. No.: US 2007/0090494 A1
(43) Pub. Date: Apr. 26, 2007

(54) Insulation-coated conductor and manufacturing method thereof

(75) Inventors: Motoaki Kimura, Kyoto-fu (JP); Iwao Hatakeyama, Kyoto-fu (JP); Takao Murakami, Kyoto-fu (JP)

Correspondence Address: STERNE, KESSLER, GOLDSTEIN & FOX P.L.L.C., 1100 NEW YORK AVENUE, N.W., WASHINGTON, DC, 20005, US

(73) Assignee: Suncall Corporation, Kyoto-fu (JP)

(21) Appl. No.: 11/584,648

(22) Filed: Oct. 23, 2006

(30) Foreign Application Priority Data
Oct. 21, 2005 (JP) 2005-307598

(51) Int. Cl. H01L 23/58

(52) U.S. Cl. 257/632

(57) ABSTRACT

There is provided an insulation-coated conductor including a conductive member that has a comer potion and a non-comer portion, and an insulating resin coated around the conductive member. The insulating resin is subjected to plastic deformation so that the insulating resin at the non-comer portion partly shifts to the comer portion after the insulating resin is applied as a coat onto the conductive member

### BACKGROUND OF THE INVENTION

1. Field of the Invention

The present invention relates to an insulation-coated conductor including a conductive member and an insulating resin applied as a coat onto the conductive member, and a manufacturing method thereof.

2. Background Art

An insulation-coated conductor including a conductive member and an insulating resin applied as a coat onto the conductive member is widely used as a winding wire, an electric wire or the like for use in a power system such as a motor or a generator.

With respect to the insulation-coated conductor, there is required improvement in space factor of the conductive member. Accordingly, in recent years, there is increasingly demanded an insulation-coated conductor including a conductive member having comer portions when being seen from its section (for example, a conductive member having a rectangular shape when being seen from its section) and an insulating resin applied as a coat onto the conductive member.

In such an insulation-coated conductor including a conductive member having comer portions when being seen from its section and an insulating resin applied as a coat onto the conductive member, however, there is no achievement in satisfactory insulation property and improvement in space factor.

As illustrated in FIG. 9(A), when an insulating resin 12 is applied as a coat onto a conductive member 11 having a comer portion C1 when being seen from its section, a thickness d1 of the insulating resin 12 at the comer portion C1 tends to be smaller than a thickness d2 of the insulating resin 12 at a non-comer portion C2 other than the comer portion C1 due to a surface tension of the insulating resin 12. As a result, the comer portion C1 fails to obtain a sufficient insulation property.

As a method of improving the insulation property at the comer portion C1, as illustrated in FIG. 9(B), an amount of the insulating resin 12 to be applied is increased, so that the thickness of the insulating resin 12 at the comer portion C1 can be made larger. In this method, however, the thickness of the insulating resin 12 at the non-corner portion C2 becomes large unnecessarily, resulting in deterioration of a space factor. In FIG. 9(B), a broken line denotes the thickness of the insulating resin 12 in a case that an amount of the insulating resin 12 to be applied is not increased.

The present invention is made in view of the conventional art. It is an object of the present invention to provide an insulation-coated conductor including a conductive member having a corner portion and a non-corner portion when being seen from its section, and an insulating resin applied as a coat onto the conductive member, the insulation-coated conductor capable of improving a space factor of the conductive member while maintaining a good insulation property.

It is another object of the present invention to provide a manufacturing method of an insulation-coated conductor including a conductive member having a corner portion and a non-corner portion when being seen from its section, and an insulating resin applied as a coat onto the conductive member, the manufacturing method capable of improving a space factor of the conductive member while maintaining a good insulation property.

### SUMMARY OF THE INVENTION

According to the present invention, there is provided an insulation-coated conductor including a conductive member that has a corner potion and a non-corner portion, and an insulating resin coated around the conductive member.

The insulating resin is subjected to plastic deformation so that the insulating resin at the non-corner portion partly shifts to the corner portion after the insulating resin is applied as a coat onto the conductive member.

According to the insulation-coated conductor, when the insulating resin is applied as a coat onto the conductive member having a corner portion and a non-corner portion when being seen from its section, even if the thickness of the insulating resin at the corner portion becomes smaller than the thickness of the insulating resin at the non-corner portion due to the surface tension of the insulating resin, the insulating resin at the non-corner portion partly shifts to the adjacent comer portion by the plastic deformation after the insulating resin is coated onto the conductive member. Therefore, it is possible to secure the thickness of the insulating resin at the corner portion without increasing a coating amount of the insulating resin. Thus, it is possible to achieve a good insulation property without worsening a space factor of the conductive member.

For example, the plastic deformation may be performed by drawing using a die.

Alternatively, the plastic deformation may be performed by pressing.

In one embodiment, the plastic deformation is performed before curing of the insulating resin applied as a coat onto the conductive member.

In another embodiment, the plastic deformation is performed after curing of the insulating resin applied as a coat onto the conductive member.

According to the present invention, there is still provided a manufacturing method of an insulation-coated conductor.

The manufacturing method according to the present invention includes a step of preparing a conductive member having a corner portion and a non-comer portion when being seen from its section; a step of applying an insulating resin as a coat onto the conductive member; and a step of performing plastic deformation of the insulating resin applied as a coat onto the conductive member so that the insulating resin at the non-corner portion partly shifts to the comer portion.

According to the manufacturing method of the insulation-coated conductor, when the insulating resin is applied as a coat onto the conductive member having a comer portion and a non-comer portion when being seen from its section, even if the thickness of the insulating resin at the comer portion becomes smaller than the thickness of the insulating resin at the non-comer portion due to the surface tension of the insulating resin, the insulating resin at the non-comer portion partly shifts to the adjacent comer portion by the plastic deformation after the insulating resin is coated onto the conductive member. Therefore, it is possible to secure the thickness of the insulating resin at the comer portion without increasing a coating amount of the insulating resin. Thus, it is possible to achieve a good insulation property without worsening a space factor of the conductive member.

### BRIEF DESCRIPTION OF THE DRAWINGS

The above, and other objects, features and advantages of the present invention will become apparent from the detailed description thereof in conjunction with the accompanying drawings wherein.

FIG. 1 is a sectional view of an insulation-coated conductor according to one embodiment of the present invention.

FIG. 2(A) is a flowchart showing one manufacturing method of the insulation-coated conductor shown in FIG. 1.

FIG. 2(B) is a flowchart showing another manufacturing method of the insulation-coated conductor shown in FIG. 1.

FIG. 3(A) is a schematic perspective view for explaining one example in which drawing process using a die is applied as a plastic deformation on an insulating resin in the insulation-coated conductor.

FIG. 3(B) is a schematic sectional view, taken along a line III(B)-III(B) in FIG. 3(A), showing a state that the conductive member coated with the insulating resin is inserted into the die.

FIG. 4(A) is a schematic sectional view of the conductive member coated with the insulating resin in a state before it is inserted into the die.

FIG. 4(B) is a schematic sectional view of the conductive member coated with the insulating resin in a state that it is inserted into the die, taken along a line IV(B)-IV(B) in FIG. 3(A).

FIG. 4(C) is a schematic sectional view of the conductive member coated with the insulating resin in a state after it is inserted into the die.

FIG. 5(A) is a schematic view for explaining one example of pressing process which is performed as a plastic deformation on the insulating resin in the insulation-coated conductor.

FIG. 5(B) is a schematic view for explaining another example of pressing process, which is performed as a plastic deformation on the insulating resin in the insulation-coated conductor.

FIG. 6(A) is a schematic sectional view of the conductive member coated with the insulating resin in a state before it is subjected to pressing process.

FIG. 6(B) is a schematic sectional view of the conductive member coated with the insulating resin, which is in course of pressing by the one pressing process.

FIG. 6(C) is a schematic sectional view of the conductive member coated with the insulating resin, which is in course of pressing by the another pressing process.

FIG. 6(D) is a schematic sectional view of the conductive member coated with the insulating resin in a state after it is subjected to pressing process.

FIG. 7 is a schematic sectional view of a modified example of the insulation-coated conductor shown in FIG. 1.

FIG. 8(A) is a schematic view for explaining a method of measuring a voltage upon start of corona discharge, which was performed onto the insulation-coated conductor shown in FIG. 1 and a prior insulation-coated conductor.

FIG. 8(B) is a sectional view taken along a line VIII(B)-VIII(B) in FIG. 8(A).

FIG. 9 is a schematic sectional view of a prior insulation-coated conductor in which a conductive member having comer portions and non-comer portions in sectional view is coated with an insulating resin.

### DETAILED DESCRIPTION OF THE PREFERRED EMBODIMENT

Hereinafter, description will be given of an embodiment of the present invention with reference to the drawings.

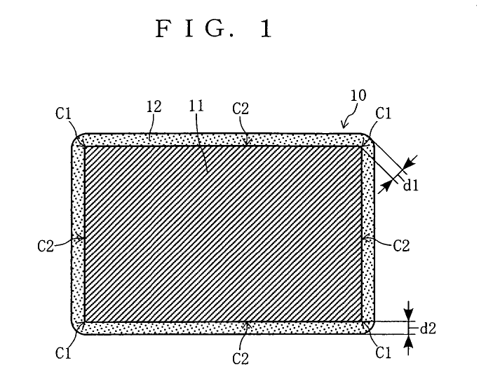

FIG. 1 is a sectional view of an insulation-coated conductor 10 according to a preferred embodiment of the present invention.

The insulation-coated conductor 10 is widely used as a winding wire, an electric wire or the like for use in a power system such as a motor or a generator.

The insulation-coated conductor 10 includes a conductive member 11 (having a rectangular shape when being seen from its section in this embodiment) having at least one comer portion C1 and a non-comer portion C2 other than the comer portion C1 when being seen from its section, and an insulating resin 12 applied as a coat onto the conductive member 11.

Specifically, the insulation-coated conductor 10 is manufactured as follows. First, the insulating resin 12 is applied as a coat onto the conductive member 11. Then, the insulating resin 12 applied as a coat onto the conductive member 11 is subjected to plastic deformation such that the insulating resin 12 at the non-comer portion C2 partly shifts to the adjacent comer portion C1.

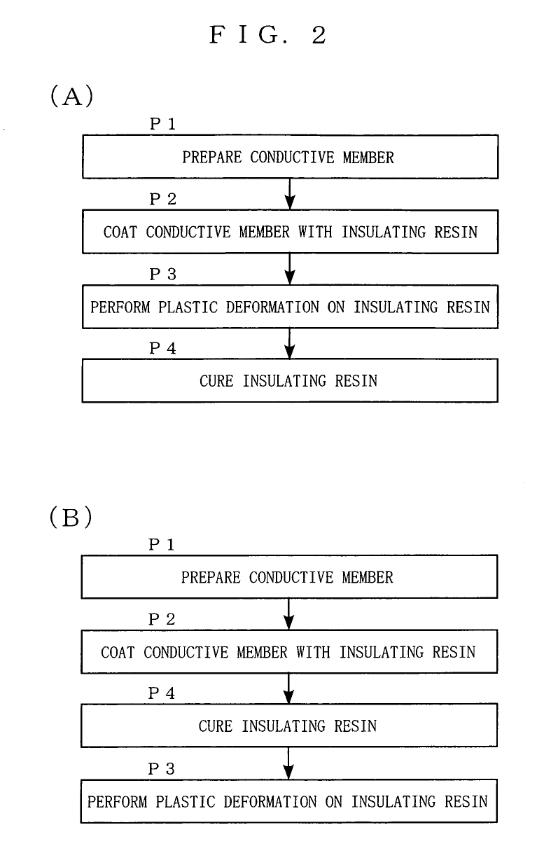

Next, description will be given of a manufacturing method of the insulation-coated conductor 10 with reference to FIGS. 2-6.

FIG. 2 shows flows of the manufacturing methods of the insulation-coated conductor 10 illustrated in FIG. 1. Specifically, FIG. 2(A) is a flowchart showing one manufacturing method in which the aforementioned plastic deformation is performed before the insulating resin 12 which has been applied as a coat onto the conductive member 11 is cured. FIG. 2(B) is a flowchart showing another manufacturing method in which the aforementioned plastic deformation is performed after the insulating resin 12 which has been applied as a coat onto the conductive member 11 is cured.

The one manufacturing method shown in FIG. 2(A) includes:
a step P1 of preparing a conductive member 11 having a comer portion C1 and a non-comer portion C2 other than the comer portion C1 when being seen from its section;
a step P2 of applying an insulating resin 12 as a coat onto the conductive member 11 by wet-on-wet coating or electrodeposition coating;
a step P3 of performing plastic deformation of the insulating resin 12 around the conductive member 11 such that the insulating resin 12 at the non-comer portion C2 partly shifts to the comer portion C1 before the insulating resin 12 which has been applied as a coat onto the conductive member 11 is cured, and
a step P4 of curing the insulating resin 12 applied as a coat onto the conductive member 11.

More specifically, the conductive member 11 having the comer portion C1 and the non-comer portion C2 when being seen from its section is prepared (step P1), and the insulating resin 12 is applied as a coat onto the conductive member 11 by wet-on-wet coating or electrodeposition coating (step P2).

When the insulating resin 12 is applied as a coat onto the conductive member 11 having the comer potion C1 and the non-comer portion C2,
a thickness d1 of the insulating resin 12 at the comer portion C1 is likely to be smaller than a thickness d2 of the insulating resin 12 at the non-comer portion C2 due to a surface tension of the insulating resin 12.

Hence, in the one manufacturing method shown in FIG. 2(A), the insulating resin 12, which is in a state before curing (semidrying state), is subjected to plastic deformation such that the insulating resin 12 at the non-comer portion C2 partly shifts to the comer portion C1 (step P3). With this step P3, the thickness d1 of the insulating resin 12 at the comer portion C1 becomes approximate to or becomes almost equal to the thickness d2 of the insulating resin 12 at the non-comer portion C2. The detailed description of the plastic deformation will be explained later.

And then, the insulating resin 12, which is in a state that the thickness d1 of the insulating resin 12 at the comer portion C1 has been approximate to or almost equal to the thickness d2 of the insulating resin 12 at the non-comer portion C2, is cured (step P4); thus, the insulation-coated conductor 10 illustrated in FIG. 1 is obtained.

On the other hand, the manufacturing method shown in FIG. 2(B) includes:
a step P1 of preparing a conductive member 11 having a comer portion C1 and a non-comer portion C2 other than the comer portion C1 when being seen from its section;
a step P2 of applying an insulating resin 12 as a coat onto the conductive member 11 by wet-on-wet coating or electrodeposition coating;
a step P4 of curing the insulating resin 12 applied as a coat onto the conductive member 11; and
a step P3 of performing plastic deformation on the insulating resin 12 applied as a coat onto the conductive member 11 such that the insulating resin 12 at the non-comer portion C2 partly shifts to the comer portion C1 after the insulating resin 12 is cured.

More specifically, the conductive member 11 having a comer portion C1 and a non-comer portion C2 when being seen from its section is prepared (step P1), the insulating resin 12 is applied as a coat onto the conductive member 11 by wet-on-wet coating or electrodeposition coating (step P2), and the insulating resin 12 that has been applied as a coat onto the conductive member 11 is cured (step P4).

In this state, a thickness d1 of the insulating resin 12 at the comer portion C1 is smaller than a thickness d2 of the insulating resin 12 at the non-comer portion C2 due to a surface tension of the insulating resin 12.

Hence, in a state that the insulating resin 12 is cured but can be subjected to plastic deformation yet, the insulating resin 12 is subjected to plastic deformation such that the insulating resin 12 at the non-comer portion C2 partly shifts to the comer portion C1 (step P3). With this step P3, the thickness d1 of the insulating resin 12 at the comer portion C1 becomes approximate to or becomes almost equal to the thickness d2 of the insulating resin 12 at the non-comer portion C2; thus, the insulation-coated conductor 10 illustrated in FIG. 1 is obtained.

Herein, description will be given of the aforementioned plastic deformation.

In the manufacturing methods shown in FIGS. 2(A) and 2(B), the plastic deformation in the step P3 may be performed by drawing process using a die or pressing process.

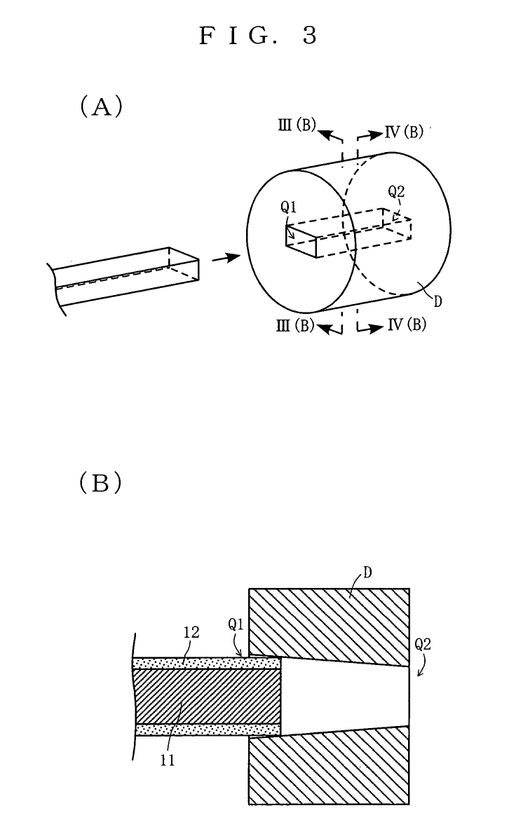

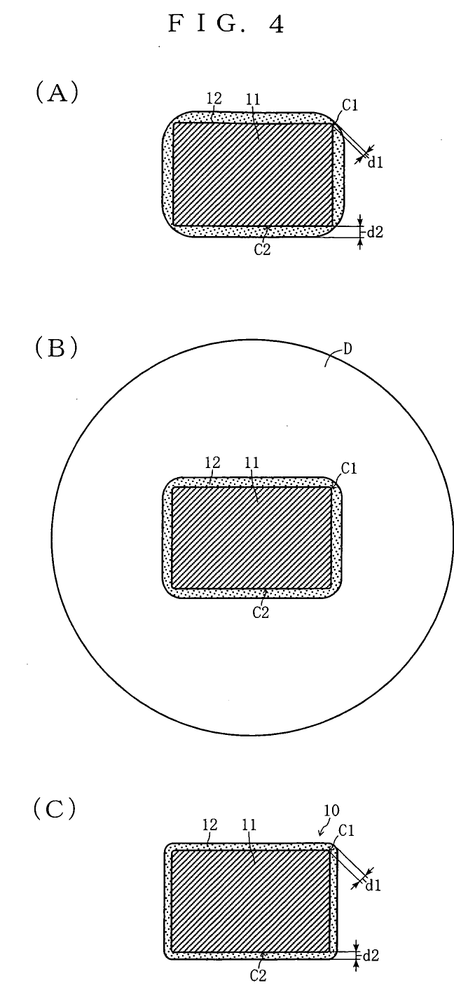

FIGS. 3 and 4 schematically illustrate the plastic deformation by drawing process using a die D.

Specifically, FIG. 3(A) is a schematic perspective view illustrating the plastic deformation by the drawing process using the die D. FIG. 3(B) is a schematic sectional view, taken along a line III(B)-III(B) in FIG. 3(A), illustrating a state that the conductive member 11 coated with the insulating resin 12 is inserted into the die D.

FIG. 4(A) is a schematic sectional view illustrating a state before the conductive member 11 coated with the insulating resin 12 is inserted into the die D. FIG. 4(B) is a schematic sectional view, taken along a line IV(B)-IV(B) in FIG. 3(A), illustrating a state that the conductive member 11 coated with the insulating resin 12 is being inserted into the die D. FIG. 4(C) is a schematic sectional view illustrating a state after the conductive member 11 coated with the insulating resin 12 is inserted into the die D.

Preferably, the die D is configured so that its opening size is larger than or almost equal to the conductive member 11 coated with the insulating resin 12 at an inlet portion Q1, and is gradually made small toward an outlet portion Q2. The opening size at the outlet portion Q2 is defined based on a size of the conductive member 11 and an amount of the insulating resin 12 to be applied, so that the thickness of the insulating resin 12 at the comer portion C1 becomes equal to the thickness of the insulating resin 12 at the non-comer portion C2.

The following advantage is obtained by drawing process using the die D. Even if the thickness d1 of the insulating resin 12 at the comer portion C1 is smaller than the thickness d2 of the insulating resin 12 at the non-comer portion C2 when the insulating resin 12 is coated onto the conductive member 11 (see FIG. 4(A)), the insulating resin 12 at the non-comer portion C2 partly shifts to the comer portion C1 (see FIG. 4(B)) by inserting the conductive member 11 coated with the insulating resin 12 into the die D. Thus, the thickness d1 of the insulating resin 12 at the comer portion C1 can be made approximate to or almost equal to the thickness d2 of the insulating resin 12 at the non-comer portion C2 (see FIG. 4(C)).

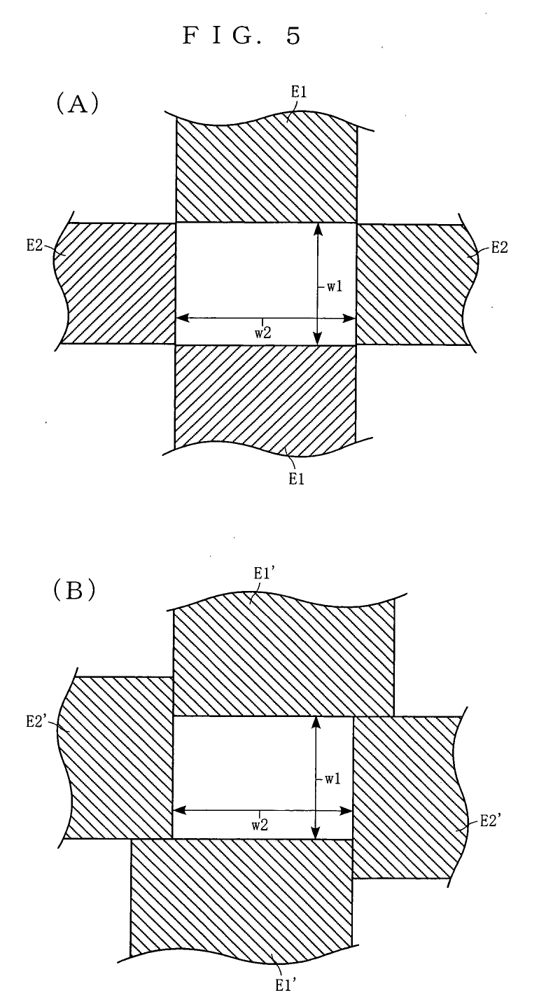

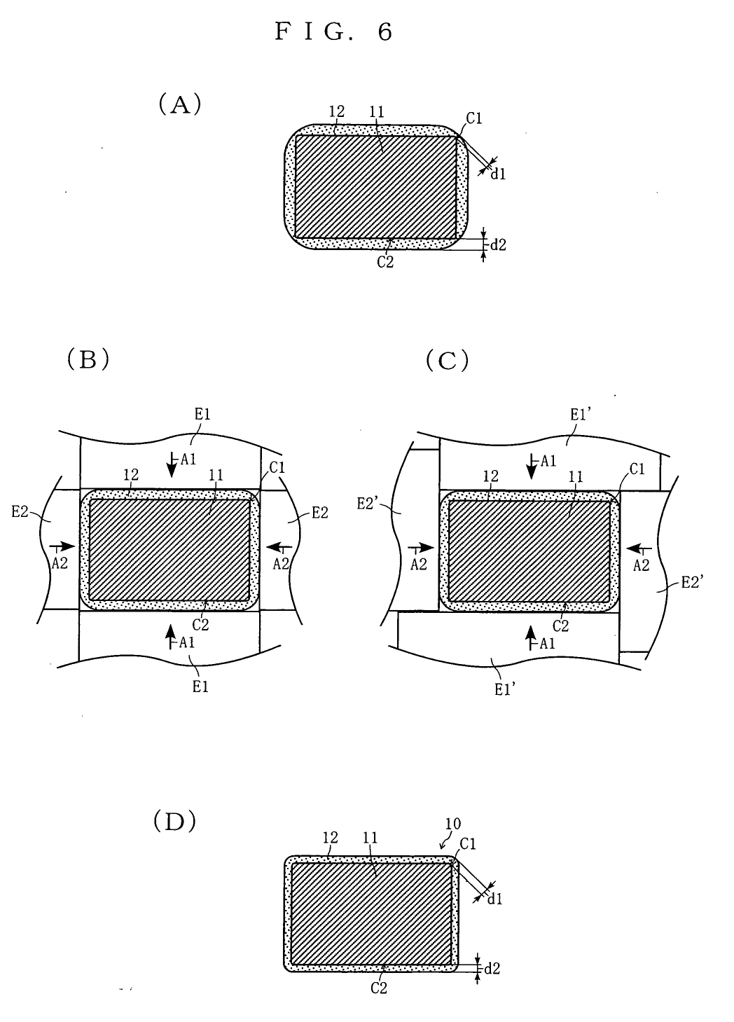

FIGS. 5 and 6 schematically illustrate the plastic deformation by pressing process.

Specifically, FIG. 5(A) is a schematic view illustrating one pressing process for performing the plastic deformation, and FIG. 5(B) is a schematic view illustrating another pressing process for performing the plastic deformation.

FIG. 6(A) is a schematic sectional view of the conductive member 11 coated with the insulating resin 12 in a state before pressing process.

FIG. 6(B) is a schematic sectional view of the conductive member 11 coated with the insulating resin 12, which is in course of pressing by the one pressing process. FIG. 6(C) is a schematic sectional view of the conductive member 11 coated with the insulating resin 12, which is in course of pressing by the another pressing process.

FIG. 6(D) is a schematic sectional view of the conductive member 11 coated with the insulating resin 12 in a state after pressing process.

In this embodiment, the conductive member 11 has an almost square shape when being seen from its section. In both of one pressing process and another pressing process described above, the conductive member 11 coated with the insulating resin 12 is formed into an almost square shape of w1×w2 after the pressing process (see FIGS. 5(A) and 5(B)).

Specifically, the one pressing process is configured to perform pressing on the conductive member 11 coated with the insulating rein 12, by using a pressing apparatus including a pair of first pressing members E1 having a pressing face whose length is w2 and opposing to each other with a space w1 between the pressing faces, and a pair of second pressing members E2 having a pressing face whose length is w1 and opposing to each other with a space w2 between the pressing faces.

In the pressing apparatus, the pair of first pressing members E1 oppose to each other and the pair of second pressing members E2 oppose to each other, so that a space of w1×w2 is defined by the pressing faces of the pair of first pressing members E1 and those of the pair of second pressing members E2.

According to the one pressing process, the insulating resin 12 is applied as a coat onto an outer periphery of the conductive member 11. Then, the pair of first pressing members E1 are pressed in a direction of an arrow A1 and the pair of second pressing members E2 are pressed in a direction of an arrow A2 in a state that the conductive member 11 with the insulating resin 12 is placed in the space defined by the pair of first pressing members E1 and the pair of second pressing members E2 (see FIG. 6(C)). Thus, it is possible to form the conductive member 11 with the insulating resin 12 having a sectional shape of w1×w2 in a state that the thickness of the insulating resin 12 is almost uniform around the outer periphery of the conductive member 11.

That is, even if the thickness d1 of the insulating resin 12 at the comer portion C1 is smaller than the thickness d2 of the insulating resin 12 at the non-comer portion C2 when the insulating resin 12 is coated onto the conductive member 11 (see FIG. 6(A)), the insulating resin 12 at the non-comer portion C2 partly shifts to the adjacent comer portion C1 by the one pressing process (see FIG. 6(B)). Thus, the thickness d1 of the insulating resin 12 at the comer portion C1 can be made approximate to or almost equal to the thickness d2 of the insulating resin 12 at the non-comer portion C2 (see FIG. 6(D)).

The another pressing process is configured to perform pressing on the conductive member 11 coated with the insulating rein 12, by using a pressing apparatus including a pair of first pressing members E1′ having a pressing face longer than w2 and opposing to each other at a space w1 between the pressing faces, and a pair of second pressing members E2′ having a pressing face longer than w1 and opposing to each other at a distance w2 between the pressing faces.

In the pressing apparatus, the pair of first pressing members E1′ oppose to each other in a state of being mutually displaced in a direction along their pressing faces and, also, the pair of second pressing members E2′ oppose to each other in a state of being mutually displaced in a direction along their pressing faces, so that a space of w1×w2 is defined by the pressing faces of the pair of first pressing members E1′ and those of the pair of second pressing members E2′.

According to the another pressing process, the insulating resin 12 is applied as a coat onto an outer periphery of the conductive member 11. Then, the pair of first pressing members E1′ are pressed in a direction of an arrow A1 and the pair of second pressing members E2′ are pressed in a direction of an arrow A2 in a state that the conductive member 11 with the insulating resin 12 is placed in the space defined by the pair of first pressing members E1′ and the pair of second pressing members E2′ (see FIG. 6(C)). Thus, it is possible to form the conductive member 11 with the insulating resin 12 having a sectional shape of w1×w2 in a state that the thickness of the insulating resin 12 is almost uniform around the outer periphery of the conductive member 11.

That is, even if the thickness d1 of the insulating resin 12 at the comer portion C1 is smaller than the thickness d2 of the insulating resin 12 at the non-comer portion C2 when the insulating resin 12 is coated onto the conductive member 11 (see FIG. 6(A)), the insulating resin 12 at the non-comer portion C2 partly shifts to the adjacent comer portion C1 by the another pressing process (see FIG. 6(C)). Thus, the thickness d1 of the insulating resin 12 at the comer portion C1 can be made approximate to or almost equal to the thickness d2 of the insulating resin 12 at the non-comer portion C2 (see FIG. 6(D)).

As described above, the insulation-coated conductor 10 and the manufacturing method of the insulation-coated conductor 10 can exhibit the following advantage. That is, when the insulating resin 12 is applied as a coat onto the conductive member 11 having the comer portion C1 and the non-comer portion C2 when being seen from its section, even if the thickness d1 of the insulating resin 12 at the comer portion C1 becomes smaller than the thickness d2 of the insulating resin 12 at the non-comer portion C2 other than the comer portion C1 due to the surface tension of the insulating resin 12, the insulating resin 12 applied as a coat onto the conductive member 11 is subjected to plastic deformation such that the insulating resin 12 at the non-comer portion C2 partly shifts to the comer portion C1. Therefore, it is possible to secure the thickness d1 of the insulating resin 12 at the comer portion C1. Thus, it is possible to achieve a good insulation property at the comer portion C1 without unnecessary increase in thickness of the insulating resin 12 at the non-comer portion C2 by increasing an amount of the insulating resin 12 to be applied onto the conductive member 11.

Accordingly, it is possible to achieve a good insulation property without deterioration in space factor of the conductive member 11.

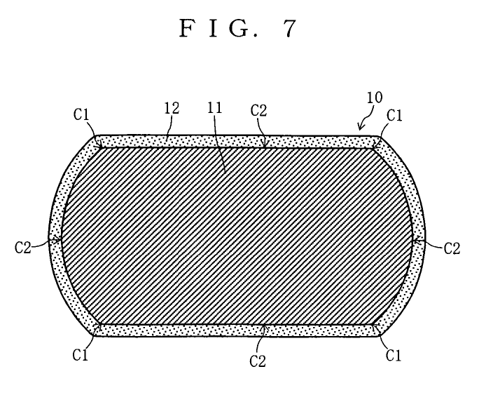

In this embodiment, the insulation-coated conductor 10 is formed into a rectangular shape in its section so as to have the comer portions C1 and the non-comer portions C2. However, it is needless to say that the present invention is not limited to this configuration. For example, as illustrated in FIG. 7, the present invention may be applicable to an insulation-coated conductor 10 including a conductive member 11 formed into a sectional shape defined by a pair of parallel sides and a pair of arcuate sides, and an insulating resin 12 applied as a coat onto an outer periphery of the conductive member 11.

### EXAMPLE

Next, description will be given of an experiment performed on the insulation-coated conductor 10 illustrated in FIG. 1 as an example and a conventional insulation-coated conductor as a comparative example. However, the present invention is not limited to the example.

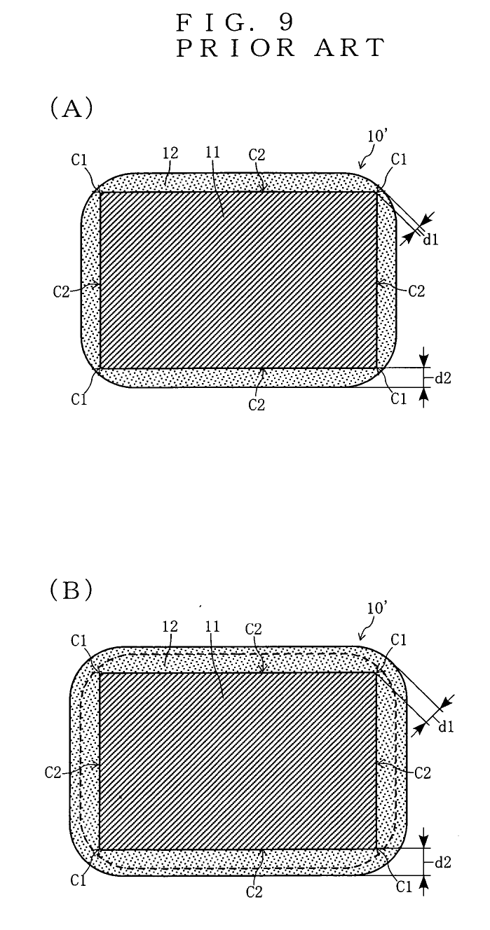

In this experiment, with respect to the insulation-coated conductor 10 obtained as follows: the conductive member 11 was coated with the insulating resin 12 and, then, the insulating resin 12 applied as a coat onto the conductive member 11 was subjected to plastic deformation such that the insulating resin 12 at the non-comer portion C2 partly shifts to the comer portion C1 (see FIG. 1, hereinafter, referred to as “example”) and a conventional insulation-coated conductor 10′ obtained as follows: the conductive member 11 was simply coated with the insulating resin 12 (see FIG. 9(A), hereinafter, referred to as “comparative example”), a voltage upon start of corona discharge was measured under identical conditions, and an insulation property of each conductor was examined.

On both the example and the comparative example, the experiment was performed under the following identical measurement conditions.

Specifically, a rectangular copper wire having a size (vertical length×lateral length) of 1.5 mm×2.3 mm when being seen from its section was used as the conductive member 11.

In view of a fact that a space factor can be improved if a comer radius R at each comer portion C1 of the conductive member 11 is not more than 0.1 mm, the comer radius R at each comer portion C1 was set at 0.05 mm in both the example and the comparative example in this experiment.

In addition, an electrocoating material of a high insulation type (INSULEED (registered trademark) made by Nippon Paint) was used as the insulating resin 12. The insulating resin 12 was applied as a coat onto the conductive member 11 by electrodeposition coating so as to have a thickness of about 100 μm.

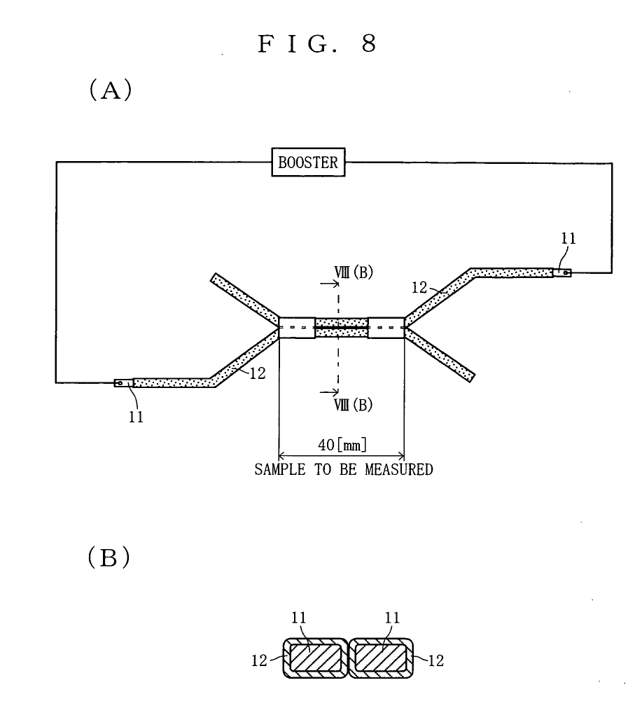

In this experiment, a voltage upon start of corona discharge was measured as follows. That is, as illustrated in FIGS. 8(A) and 8(B), two insulation-coated conductors were brought into contact with each other in a longitudinal direction so as to have a contact length of 40 mm, and a voltage upon start of corona discharge was measured at the contact length.

Specifically, a voltage at the two insulation-coated conductors was boosted by means of a booster. Then, a voltage when electrical discharge of not less than 10 pC occurred at the contact length of 40 mm was measured as the voltage upon start of corona discharge. In this experiment, this measurement for the voltage upon start of corona discharge was performed three times and, then, an average of resulting measurement values was calculated.

In view of the aforementioned measurement conditions in this experiment, if a voltage upon start of corona discharge is not less than 1200 V, it can be evaluated that an insulation property is good.

Measurement results are shown in Table 1.

| Example | | | Comparative example | | |
|---|---|---|---|---|---|
| Corner | | Voltage upon | Corner | | Voltage upon |
| radius R | | start of corona | radius R | | start of corona |
| (mm) | | discharge (V) | (mm) | | discharge (V) |
| 0.05 | No. 1 | 1320 | 0.05 | No. 1 | 1040 |
| | No. 2 | 1330 | | No. 2 | 1030 |
| | No. 3 | 1230 | | No. 3 | 1020 |
| | Average | 1293 | | Average | 1030 |

As shown in Table 1, in the example, the voltage upon start of corona discharge was 1293 V on average although the comer radius R at each comer portion C1 was set at 0.05 mm which is not more than 0.1 mm; therefore, a target value of the voltage upon start of corona discharge was satisfied.

On the other hand, in the comparative example, the voltage upon start of corona discharge was 1030 V on average; therefore, a target value of the voltage upon start of corona discharge was not satisfied.

It is apparent from the example and the comparative example that the insulation-coated conductor 10 according to the aforementioned embodiment can prevent deterioration in insulation property while achieving an improved space factor of the conductive member 11 by making the corner radius R at each comer portion C1 small.

This specification is by no means intended to restrict the present invention to the preferred embodiment set forth therein. Various modifications to the insulation-coated conductor as well as manufacturing method thereof may be made by those skilled in the art without departing from the spirit and scope of the present invention as defined in the appended claims.

What is claimed is:

1. An insulation-coated conductor comprising a conductive member that has a comer potion and a non-comer portion, and an insulating resin coated around the conductive member, wherein
(a) the insulating resin is subjected to plastic deformation after the insulating resin is applied as a coat onto the conductive member so that the insulating resin at the non-comer portion partly shifts to the comer portion.

2. An insulation-coated conductor according to claim 1, wherein
(a) the plastic deformation is performed by drawing process using a die.

3. An insulation-coated conductor according to claim 1, wherein
(a) the plastic deformation is performed by pressing process.

4. An insulation-coated conductor according to claim 1, wherein
(a) the plastic deformation is performed before the insulating resin applied as a coat onto the conductive member is cured.

5. An insulation-coated conductor according to claim 1, wherein
(a) the plastic deformation is performed after the insulating resin applied as a coat onto the conductive member is cured.

6. A manufacturing method of an insulation-coated conductor including;
(a) a step of preparing a conductive member having a comer portion and a non-comer portion when being seen from its section;
(b) a step of applying an insulating resin as a coat onto the conductive member; and
(c) a step of performing plastic deformation on the insulating resin applied as a coat onto the conductive member so that the insulating resin at the non-comer portion partly shifts to the comer portion.
